(19) United States
(12) Patent Application Publication
(10) Pub. No.: US 2026/0280264 A1
(43) Pub. Date: Sep. 17, 2026

(54) SEMICONDUCTOR PROTECTION DEVICE AND ELECTRIC POWER CONVERSION DEVICE

(71) Applicant: MITSUBISHI ELECTRIC CORPORATION, Tokyo (JP)

(72) Inventors: Tatsuki MATSUNAGA, Tokyo (JP); Kohei ONDA, Tokyo (JP); Chiharu MORISAKI, Tokyo (JP); Tomoya HARA, Tokyo (JP)

(73) Assignee: MITSUBISHI ELECTRIC CORPORATION, Tokyo (JP)

(21) Appl. No.: 19/479,748

(22) PCT Filed: Jun. 22, 2023
(86) PCT No.: PCT/JP2023/023088

§ 371 Date: Oct. 29, 2025

(51) Int. Cl. H02H 1/00; G01R 19/165; G01R 31/52; H02H 7/122

(52) U.S. Cl. CPC H02H 1/0007; G01R 19/16571; G01R 19/16576; G01R 31/52; H02H 7/122

(57) ABSTRACT

This semiconductor protection device includes: a first determination unit which outputs a first output signal when gate voltage of a semiconductor switching element has exceeded a predetermined first threshold; a second determination unit which outputs a second output signal when the gate voltage has exceeded a second threshold greater than the first threshold; and a third determination unit which outputs a third output signal when a value based on voltage of the semiconductor switching element or a value based on a value of current flowing through the semiconductor switching element during a period in which the semiconductor switching element is turned ON has exceeded a third threshold.

Determination operation of the third determination unit is activated by the first output signal, and a short-circuit state of the semiconductor switching element is detected on the basis of a logical conjunction of the second output signal and the third output signal.

### TECHNICAL FIELD

The present disclosure relates to a semiconductor protection device and an electric power conversion device.

### BACKGROUND ART

Conventionally, in an electric power conversion device having a bridge circuit composed of semiconductor switching elements, when a short-circuit state occurs due to failure or erroneous operation and overcurrent flows through upper and lower arms, a protection device detects the short-circuit state and protects the electric power conversion device from large-scale destruction. Hereinafter, overcurrent flowing through upper and lower arms is referred to as short-circuit current, and detection for a short-circuit state is referred to as short-circuit detection.

The short-circuit current has a greater value than current assumed in normal operation of the electric power conversion device. Therefore, if protection is not performed early, the semiconductor switching elements might be broken. Thus, it is required to perform short-circuit detection fast and protect the semiconductor switching elements from breakage.

As a technology regarding protection of semiconductor switching elements by short-circuit detection, there is known a short-circuit detection technology that is called desaturation (Desat) detection and uses the potential of a high-potential terminal of a semiconductor switching element (see, for example, Patent Document 1). In the Desat detection, a detected value of the potential of the high-potential terminal is compared with a threshold for the potential of the high-potential terminal, to perform short-circuit detection.

The technology disclosed in Patent Document 1 has a circuit in which the potential of a high-potential terminal of a semiconductor switching element is detected using a diode, a current source, and a capacitor connected to the high-potential terminal, and the detected potential is compared with a threshold, to perform short-circuit detection, and the potential of the high-potential terminal is set at low voltage until voltage of a control terminal of the semiconductor switching element exceeds a threshold, thereby preventing erroneous detection for short-circuit.

In addition, until the voltage of the control terminal of the semiconductor switching element exceeds the threshold, the threshold for the potential of the high-potential terminal is set to be high, and after the threshold is exceeded, the threshold is changed to be low. Thus, short-circuit detection can be performed early in a case where short-circuit has occurred after the semiconductor switching element is turned on.

### CITATION LIST

### Patent Document

Patent Document 1: Japanese Patent No. 7,183,375

### SUMMARY OF THE INVENTION

### PROBLEM TO BE SOLVED BY THE INVENTION

However, in the technology disclosed in Patent Document 1, the threshold for the control terminal of the semiconductor switching element is set to be Miller voltage or greater. Therefore, until the threshold is exceeded, Desat detection cannot be executed because of a lock circuit, so that short-circuit detection is delayed, leading to breakage of the semiconductor switching element.

The present disclosure has been made to solve the above problem, and an object of the present disclosure is to provide a semiconductor protection device that can perform fast short-circuit detection.

### Means to Solve the Problem

A semiconductor protection device according to the present disclosure is a semiconductor protection device which outputs a short-circuit detection signal to a gate drive circuit in a case where a semiconductor switching element is determined to be in a short-circuit state, the semiconductor protection device including: a first determination unit which outputs a first output signal when gate voltage of the semiconductor switching element has exceeded a predetermined first threshold; a second determination unit which outputs a second output signal when the gate voltage has exceeded a second threshold greater than the first threshold; and a third determination unit which outputs a third output signal when a value based on voltage of the semiconductor switching element or a value based on a value of current flowing through the semiconductor switching element during a period in which the semiconductor switching element is turned ON has exceeded a third threshold. The third determination unit is activated by the third threshold being reduced by the first output signal, and a short-circuit state of the semiconductor switching element is detected on the basis of a logical conjunction of the second output signal and the third output signal.

### Effect of the Invention

In the semiconductor protection device according to the present disclosure, when the gate voltage of the semiconductor switching element has become greater than the first threshold, determination operation of an output determination unit is activated, thus enabling fast short-circuit detection.

### BRIEF DESCRIPTION OF THE DRAWINGS

FIG. 1 is a block configuration diagram showing a basic configuration of a semiconductor protection device according to embodiment 1.

FIG. 2 shows an example of a circuit in Example 1 of the semiconductor protection device according to embodiment 1.

FIG. 3 is a time chart in normal driving in Example 1.

FIG. 4 is a time chart in driving in a short-circuit occurring state in Example 1.

FIG. 5 shows an example of a circuit in Example 2 of the semiconductor protection device according to embodiment 1.

FIG. 6 shows an example of a circuit in Example 3 of the semiconductor protection device according to embodiment 1.

FIG. 7 shows an example of a circuit in Example 4 of the semiconductor protection device according to embodiment 1.

FIG. 8 shows an example of a circuit in Example 5 of the semiconductor protection device according to embodiment 1.

FIG. 9 is a time chart in normal driving in Example 5.

FIG. 10 is a time chart in driving in a short-circuit occurring state in Example 5.

FIG. 11 shows an example of a circuit in Example 6 of the semiconductor protection device according to embodiment 1.

FIG. 12 is a time chart in normal driving in Example 6.

FIG. 13 is a time chart in driving in a short-circuit occurring state in Example 6.

FIG. 14 shows an example of a circuit in Example 7 of the semiconductor protection device according to embodiment 1.

FIG. 15 shows another example of a circuit in Example 7 of the semiconductor protection device according to embodiment 1.

FIG. 16 is a time chart in normal driving in Example 7.

FIG. 17 is a time chart in driving in a short-circuit occurring state in Example 7.

FIG. 18 is a block diagram showing a basic configuration of a semiconductor protection device according to embodiment 2.

FIG. 19 is a block diagram showing a basic configuration of a semiconductor protection device according to embodiment 3.

FIG. 20 is a schematic configuration diagram of an electric power conversion device including a semiconductor protection device according to embodiment 4.

### DESCRIPTION OF EMBODIMENTS

Hereinafter, preferred embodiments of a semiconductor protection device according to the present disclosure will be described with reference to the drawings. The same or corresponding matters and parts are denoted by the same reference characters, and the detailed description thereof is omitted. Also in the other embodiments, components denoted by the same reference characters will not be repeatedly described.

### Embodiment 1

### Basic Configuration of Semiconductor Protection Device According to Embodiment 1

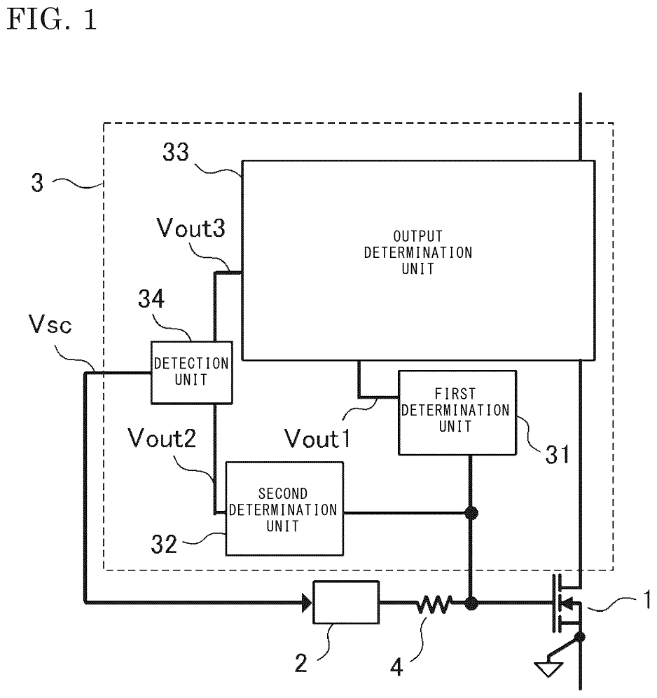

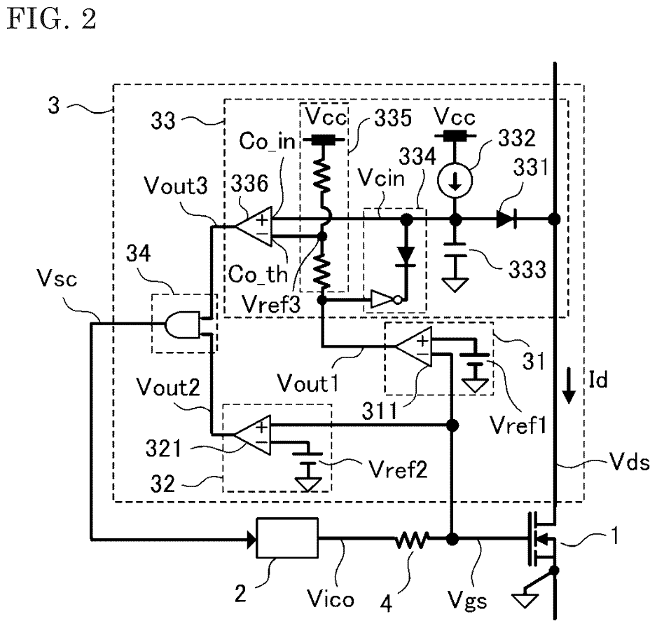

FIG. 1 is a block diagram showing a basic configuration of a semiconductor protection device according to embodiment 1, and FIG. 2 shows an example of a circuit diagram in Example 1 of the semiconductor protection device according to embodiment 1.

The semiconductor protection device according to embodiment 1 includes a semiconductor switching element 1, a gate drive circuit 2 for driving the semiconductor switching element 1, a semiconductor protection device 3 which outputs a short-circuit detection signal Vsc to the gate drive circuit 2 in a case where the semiconductor switching element 1 is determined to be in a short-circuit state, and a gate resistor 4 connected between the gate drive circuit 2 and a control terminal, i.e., a gate terminal, of the semiconductor switching element 1.

### Overall Explanation of Configuration of Semiconductor Protection Device in Example 1

As an example of the semiconductor protection device according to embodiment 1 having the basic configuration shown in FIG. 1, Example 1 will be described with reference to FIG. 2. The semiconductor switching element 1 is shown as a MOSFET (Metal-Oxide-Semiconductor Field-Effect Transistor), but is not limited to a MOSFET. For example, an IGBT (Insulated Gate Bipolar Transistor) or the like may be used.

In FIG. 2, the gate drive circuit 2 outputs a gate drive signal Vico for switching ON and OFF of the semiconductor switching element 1.

When the gate drive signal Vico has high voltage, gate current flows through the gate resistor 4, thereby increasing control terminal voltage (hereinafter, referred to as gate voltage Vgs) of the semiconductor switching element 1, so that the semiconductor switching element 1 is turned on.

The semiconductor protection device 3 includes a first determination unit 31, a second determination unit 32, an output determination unit 33, and a short-circuit detection unit 34.

The first determination unit 31 is provided with a first threshold Vref1 for the gate voltage Vgs, and compares the gate voltage Vgs with the first threshold Vref1.

When the gate voltage Vgs has become greater than (has exceeded) the first threshold Vref1, the first determination unit 31 outputs a first determination result Vout1 to the output determination unit 33.

The second determination unit 32 is provided with a second threshold Vref2 for the gate voltage Vgs, and compares the gate voltage Vgs with the second threshold Vref2.

When the gate voltage Vgs has exceeded the second threshold Vref2, the second determination unit 32 outputs a second determination result Vout2 to the short-circuit detection unit 34. The first threshold Vref1 is set to be smaller than the second threshold Vref2.

The output determination unit 33 is provided with a third threshold Vref3, and compares voltage of a high-potential terminal or a low-potential terminal of the semiconductor switching element 1, a detection value obtained by detecting current flowing through the semiconductor switching element 1, or a calculated value based on the detection value, with the third threshold Vref3. In a case where the third threshold Vref3 is exceeded and the first determination result Vout1 is inputted, the output determination unit 33 outputs a third determination result Vout3 to the short-circuit detection unit 34.

When the second determination result Vout2 and the third determination result Vout3 are inputted, the short-circuit detection unit 34 determines that the semiconductor switching element 1 is in a short-circuit state, and outputs the short-circuit detection signal Vsc to the gate drive circuit 2.

When the short-circuit detection signal Vsc is inputted, the gate drive circuit 2 sets the gate drive signal Vico to be low voltage.

When the gate drive signal Vico has become low voltage, gate current flows through the gate resistor 4 by the charged gate voltage Vgs. Thus, the gate voltage Vgs is reduced, so that the semiconductor switching element 1 is turned off.

As described above, in a state in which the semiconductor switching element 1 is turned on and the gate voltage Vgs is increased, if the gate voltage Vgs exceeds the first threshold Vref1 set to be lower than the second threshold Vref2, the output determination unit 33 is activated, whereby short-circuit detection can be performed early.

On the other hand, until the first determination result Vout1 outputted from the first determination unit 31 is inputted, the short-circuit detection unit 34 does not detect short-circuit of the semiconductor switching element 1. Therefore, for example, even if the second determination unit 32 erroneously operates due to noise or the like and outputs the second determination result Vout2, since the third determination result Vout3 is not outputted, erroneous determination that the semiconductor switching element 1 is in a short-circuit state does not occur, thus providing an effect of preventing the short-circuit detection signal Vsc from being outputted.

In addition, the short-circuit detection unit 34 does not determine short-circuit of the semiconductor switching element 1 until the second determination result Vout2 outputted from the second determination unit 32 is inputted. Therefore, for example, even if the output determination unit 33 erroneously operates due to noise or the like and outputs the third determination result Vout3, the second determination result Vout2 is not outputted, thus providing an effect of preventing the semiconductor switching element 1 from being erroneously determined to be in a short-circuit state and preventing the short-circuit detection signal Vsc from being outputted.

### Detailed Explanation of Configuration of Semiconductor Protection Device in Example 1

In FIG. 2, a circuit configuration of the semiconductor protection device according to Example 1 will be described in detail.

In FIG. 2, the first determination unit 31 includes a first comparator 311, and the first comparator 311 compares the first threshold Vref1 with the gate voltage Vgs.

In comparison between the first threshold Vref1 and the gate voltage Vgs, if the first threshold Vref1 is greater, the first comparator 311 outputs the first determination result Vout1 as high voltage.

In comparison between the first threshold Vref1 and the gate voltage Vgs, if the gate voltage Vgs is greater, the first comparator 311 outputs the first determination result Vout1 as low voltage.

The second determination unit 32 includes a second comparator 321, and the second comparator 321 compares the second threshold Vref2 with the gate voltage Vgs.

In comparison between the second threshold Vref2 and the gate voltage Vgs, if the second threshold Vref2 is greater, the second comparator 321 outputs the second determination result Vout2 as low voltage.

On the other hand, if the gate voltage Vgs is greater, the second comparator 321 outputs the second determination result Vout2 as high voltage.

The output determination unit 33 includes a diode 331, a current source 332, a Desat capacitor 333, a detection lock section 334, a third threshold change section 335, and a third comparator 336.

A cathode of the diode 331 is connected to a drain terminal of the semiconductor switching element 1 which is the high-potential terminal of the semiconductor switching element 1, and an anode of the diode 331 is connected to an input terminal Co_in of the third comparator 336.

One diode 331 is provided in the shown configuration, but a plurality of diodes may be provided or another rectification element may be used.

The current source 332 is connected between a control power supply Vcc and the input terminal Co_in of the third comparator 336, and the Desat capacitor 333 is connected between the input terminal Co_in of the third comparator 336 and a source terminal of the semiconductor switching element 1 which is a reference potential.

The detection lock section 334 is connected between the input terminal Co_in of the third comparator 336 and the first determination unit 31.

The detection lock section 334 retains input terminal voltage Vcin of the third comparator 336 at low voltage until the first determination result Vout1 outputted from the first determination unit 31 is inputted.

Specifically, the detection lock section 334 is composed of a diode and a logic inversion element. An anode of the diode of the detection lock section 334 is connected to the input terminal Co_in of the third comparator 336, a cathode of the detection lock section 334 is connected to the output side of the logic inversion element, and the input side of the logic inversion element is connected to the output side of the first determination unit 31.

In a case where the first determination result Vout1 is high voltage, the detection lock section 334 sets the cathode side of the diode at low voltage by the logic inversion element, so as to conduct current from the current source 332, thereby retaining the input terminal voltage Vcin of the third comparator 336 at low voltage.

On the other hand, in a case where the first determination result Vout1 is low voltage, the detection lock section 334 sets the cathode side of the diode at high voltage by the logic inversion element, so as to interrupt current from the current source 332, thereby releasing low-voltage retention of the input terminal voltage Vcin of the third comparator 336.

In FIG. 2, the detection lock section 334 having one diode and one logic inversion element is shown. However, the configuration is not limited thereto. For example, a resister may be further connected to the diode and the logic inversion element, or a plurality of diodes and a plurality of logic inversion elements may be connected.

The third threshold change section 335 is connected between a threshold input terminal Co_th of the third comparator 336 and the first determination unit 31. In a case where the first determination result Vout1 outputted from the first determination unit 31 is high voltage, the third threshold change section 335 retains threshold input terminal voltage Vco_th of the third comparator 336 at high voltage.

In a case where the first determination result Vout1 outputted from the first determination unit 31 is low voltage, the third threshold change section 335 outputs the third threshold Vref3 to the threshold input terminal Co_th of the third comparator 336.

Specifically, the third threshold change section 335 includes two resistors which are connected in series. One end of the series connected resistors is connected to the control power supply Vcc, the other end is connected to the first determination unit 31, and a connection point of the series connected resistors is connected to the threshold input terminal Co_th of the third comparator 336.

In a case where the first determination result Vout1 is high voltage, the third threshold change section 335 retains the threshold input terminal voltage Vco_th of the third comparator 336 at high voltage, and in a case where the first determination result Vout1 is low voltage, the third threshold change section 335 can output the third threshold Vref3 based on the voltage division ratio of the two resistors and the voltage value of the control power supply Vcc, so as to have a value reduced from high voltage.

The third threshold change section 335 having two resisters is shown, but is not limited to this configuration. For example, more than two resisters may be used, or a diode may be added to one of the two resistors that is connected to the first determination unit 31.

In comparison between the input terminal voltage Vcin and the threshold input terminal voltage Vco_th, if the threshold input terminal voltage Vco_th is greater, the third comparator 336 outputs the third determination result Vout3 as low voltage. On the other hand, if the input terminal voltage Vcin of the third comparator 336 is greater, the third comparator 336 outputs the third determination result Vout3 as high voltage.

In a case where a logical conjunction of the second determination result Vout2 outputted from the second determination unit 32 and the third determination result Vout3 outputted from the output determination unit 33 is 1, the short-circuit detection unit 34 outputs the short-circuit detection signal Vsc to the gate drive circuit 2.

### Operation in Normal Driving of Semiconductor Protection Device in Example 1

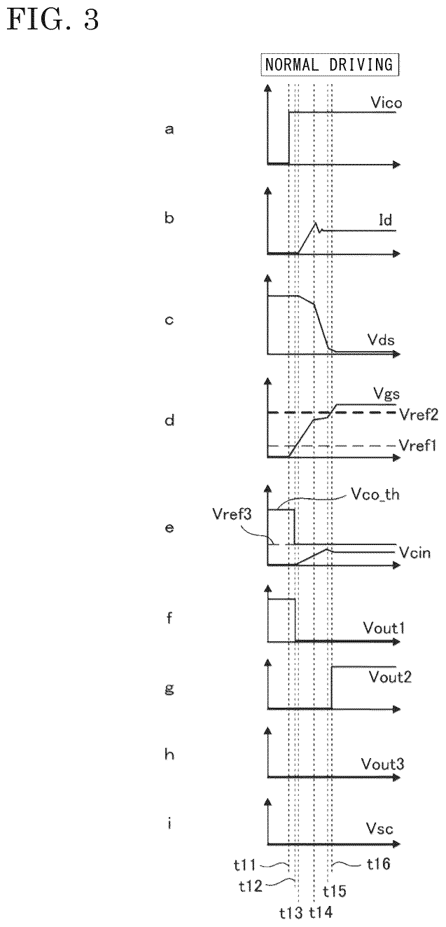

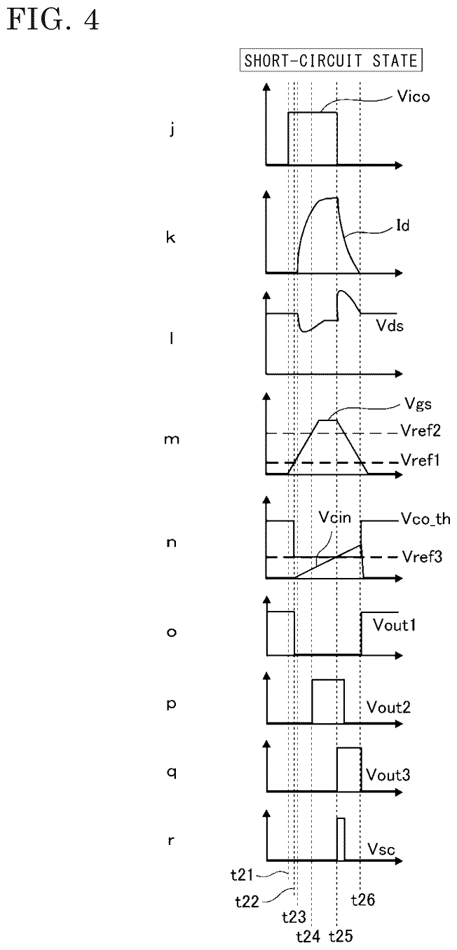

Next, operation of the semiconductor protection device according to Example 1 will be described with reference to FIG. 3 and FIG. 4. FIG. 3 is a time chart illustrating operation in normal driving of the semiconductor switching element 1.

In FIG. 3, when the gate drive signal Vico has become high voltage at time t11 (FIG. 3a), the gate voltage Vgs starts to increase (FIG. 3d). At time t12, the gate voltage Vgs exceeds the first threshold Vref1 (FIG. 3d), and the first determination unit 31 outputs the first determination result Vout1 as low voltage (FIG. 3f).

At time t12, when the first determination result Vout1 is inputted, the detection lock section 334 releases low-voltage retention of the input terminal Co_in of the third comparator 336 (FIG. 3e).

In addition, at time t12, when the first determination result Vout1 is inputted, the third threshold change section 335 releases high-voltage retention and outputs the third threshold Vref3 to the threshold input terminal Co_th of the third comparator 336 (FIG. 3e).

Further, at time t12, since high-voltage retention of the detection lock section 334 is released, current from the current source 332 flows into the Desat capacitor 333, and the input terminal voltage Vcin of the third comparator 336 starts to increase by a change degree according to the flowing current amount and the capacitance of the Desat capacitor 333 (FIG. 3e).

At time t13, when the gate voltage Vgs exceeds an ON voltage threshold of the semiconductor switching element 1, the semiconductor switching element 1 is turned on, drain current Id which is main current of the semiconductor switching element 1 starts to be conducted (FIG. 3b), and drain voltage Vds which is high-potential terminal voltage of the semiconductor switching element 1 starts to be reduced (FIG. 3c).

Here, setting is made so that low voltage of the first determination result Vout1 is outputted before the gate voltage Vgs exceeds the first threshold Vref1 (FIG. 3d and FIG. 3f). However, setting may be made so that low voltage of the first determination result Vout1 is outputted after the first threshold Vref1 is exceeded. The first threshold Vref1 may be set as the ON voltage threshold of the semiconductor switching element 1, but the present disclosure is not limited thereto.

At time t14, charging for a Miller capacitance of the semiconductor switching element 1 is started, so that the increase speed of the gate voltage Vgs is lowered (FIG. 3d).

A period from time t14 to time t15 is a period in which the Miller capacitance of the semiconductor switching element 1 is charged, and this period may be called a Miller period. Also in the Miller period, the drain voltage Vds is reduced (FIG. 3c), and the change degree in the period from time t14 to time t15 is greater than the change degree in a period from time t13 to time t14.

At time t15, when the drain voltage Vds is reduced, current from the current source 332 starts to flow into the semiconductor switching element 1 through the diode 331, so that the input terminal voltage Vcin of the third comparator 336 does not increase any longer (FIG. 3e).

As the drain voltage Vds is further reduced, an electric charge stored in the Desat capacitor 333 is discharged to the semiconductor switching element 1 through the diode 331, so that the input terminal voltage Vcin of the third comparator 336 is reduced (FIG. 3e).

At time t16, the gate voltage Vgs exceeds the second threshold Vref2 (FIG. 3d), and the second determination unit 32 outputs the second determination result Vout2 as high voltage (FIG. 3g).

After time t16, the input terminal voltage Vcin of the third comparator 336 converges to the sum of the drain voltage Vds and ON voltage of the diode 331 (FIG. 3e).

Since the ON voltage of diode 331 can be obtained on the basis of designing, the output determination unit 33 can detect the value of the drain voltage Vds.

During a period from time t11 to time t16 and after time t16, the input terminal voltage Vcin of the third comparator 336 does not exceed the threshold input terminal voltage Vco_th of the third comparator 336 (FIG. 3e), and therefore the third determination result Vout3 is retained at low voltage and high voltage is not outputted (FIG. 3h).

In FIG. 3, during the period from time t11 to time t16 and after time t16, the third determination result Vout3 is retained at low voltage. However, the third threshold Vref3 may be set so that the input terminal voltage Vcin of the third comparator 336 becomes smaller than the threshold input terminal voltage Vco_th of the third comparator 336 before time t16 when the second determination result Vout2 is outputted.

As described above, the third threshold Vref3 is set so that the third determination result Vout3 becomes low voltage at least before time t16.

In the short-circuit detection unit 34, a logical conjunction of the second determination result Vout2 and the third determination result Vout3 does not become 1 and therefore the short-circuit detection signal Vsc is retained at low voltage (FIG. 3i).

Thus, since the short-circuit detection signal Vsc is not inputted to the gate drive circuit 2, the semiconductor switching element 1 is not turned off.

### Operation in Short-Circuit Occurring State of Semiconductor Protection Device in Example 1

FIG. 4 is a time chart illustrating operation in driving in a short-circuit occurring state of the semiconductor switching element 1 according to Example 1.

In FIG. 4, at time t21, the gate drive circuit 2 outputs the gate drive signal Vico as high voltage (FIG. 4a), and the gate voltage Vgs starts to increase (FIG. 4m).

At time t22, the gate voltage Vgs becomes the first threshold Vref1 (FIG. 4m), and the first determination unit 31 outputs the first determination result Vout1 as low voltage (FIG. 4o).

At time t22, when the first determination result Vout1 is inputted, the detection lock section 334 releases low-voltage retention of the input terminal voltage Vcin of the third comparator 336 (FIG. 4n).

In addition, at time t22, when the first determination result Vout1 is inputted, the third threshold change section 335 releases high-voltage retention and outputs the third threshold Vref3 to the threshold input terminal Co_th of the third comparator 336 (FIG. 4n).

In addition, at time t22, since low-voltage retention of the detection lock section 334 is released, current from the current source 332 flows into the Desat capacitor 333, and the input terminal voltage Vcin of the third comparator 336 starts to increase in accordance with the flowing current amount and the capacitance of the Desat capacitor 333 (FIG. 4n).

At time t23, when the gate voltage Vgs exceeds the ON voltage threshold of the semiconductor switching element 1, the semiconductor switching element 1 is turned on, and the drain current Id starts to be conducted (FIG. 4k). When the drain current Id starts to be conducted, the drain voltage Vds starts to be reduced (FIG. 4l).

However, in FIG. 4, unlike FIG. 3, since the semiconductor switching element 1 is driven in a short-circuit occurring state, the change degree of the drain voltage Vds is smaller than in normal driving, and the drain voltage Vds is retained to be high.

Since the drain voltage Vds is not reduced, current from the current source 332 does not flow into the semiconductor switching element 1 through the diode 331, and the input terminal voltage Vcin of the third comparator 336 continues to increase.

Since the semiconductor switching element 1 is driven in a short-circuit occurring state, the gate voltage Vgs does not undergo a Miller period, and therefore the increase speed of the gate voltage Vgs is not reduced.

At time t24, the gate voltage Vgs exceeds the second threshold Vref2 (FIG. 4m), so that the second determination unit 32 outputs the second determination result Vout2 as high voltage (FIG. 4p).

At time t25, the input terminal voltage Vcin of the third comparator 336 exceeds the threshold input terminal voltage Vco_th of the third comparator 336 (FIG. 4n), so that the output determination unit 33 outputs the third determination result Vout3 as high voltage (FIG. 4q).

At time t25, a logical conjunction of the second determination result Vout2 and the third determination result Vout3 becomes 1, so that the short-circuit detection unit 34 outputs the short-circuit detection signal Vsc as high voltage (FIG. 4r).

In addition, at time t25, since the short-circuit detection signal Vsc is inputted, the gate drive circuit 2 outputs the gate drive signal Vico as low voltage (FIG. 4j), so that the gate voltage Vgs starts to be reduced (FIG. 4m).

At time t26, interruption of the drain current Id is completed (FIG. 4k).

Thus, Example 1 of the semiconductor protection device according to embodiment 1 can prevent erroneous determination for a short-circuit state in normal driving of the semiconductor switching element 1 and protect the semiconductor switching element 1 from being broken in driving in a short-circuit state, owing to the following actions.

(1) When the gate voltage Vgs of the semiconductor switching element exceeds the first threshold Vref1, the third threshold Vref3 is reduced, to activate determination operation of the output determination unit 33. Thus, fast short-circuit detection can be performed.

(2) Until the gate voltage Vgs of the control terminal of the semiconductor switching element becomes greater than the first threshold Vref1, the threshold for the potential of the high-potential terminal is set to be high (high voltage), and after the threshold is exceeded, the third threshold Vref3 is changed to be low, whereby short-circuit detection can be performed early in a case where short-circuit has occurred after the semiconductor switching element is turned on.

(3) Until the voltage of the control terminal of the semiconductor switching element becomes greater than the first threshold Vref1, the input terminal voltage Vcin of the high-potential terminal is set to a low potential, whereby erroneous detection of short-circuit can be prevented.

### Semiconductor Protection Device in Example 2

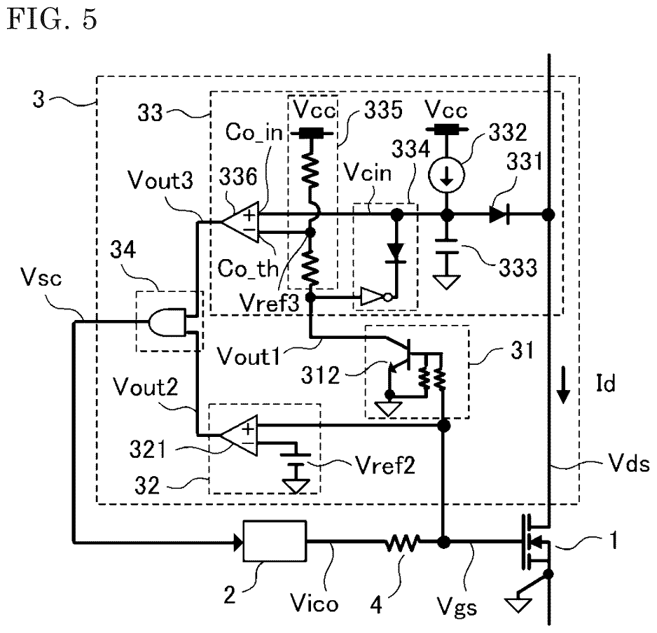

As an example of the semiconductor protection device according to embodiment 1 having the basic configuration shown in FIG. 1, Example 2 will be described with reference to FIG. 5. The same components as in FIG. 2 are denoted by the same reference characters and the description thereof is omitted. In FIG. 5, a difference from Example 1 is that the first determination unit 31 includes a transistor element 312. The transistor element 312 is shown as a bipolar transistor, but is not limited to a bipolar transistor. For example, a MOSFET or the like may be used.

In FIG. 5, a base terminal of the transistor element 312 is connected to a gate terminal of the semiconductor switching element 1 via a resister element, and an emitter terminal of the transistor element 312 is connected to a reference potential.

A collector terminal of the transistor element 312 corresponds to the first determination result Vout1 to be outputted from the first determination unit 31, and outputs the first determination result Vout1 to the output determination unit 33.

The first threshold Vref1 set in the first determination unit 31 corresponds to an ON voltage threshold of the transistor element 312.

When the gate voltage Vgs has become greater than the ON voltage threshold of the transistor element 312, the transistor element 312 is turned on and low voltage is outputted from the collector terminal of the transistor element 312.

As described above, even in the case of using the transistor element 312 in the first determination unit 31, the same effects as in Example 1 are provided, and in addition, an effect of decreasing circuit elements is provided.

### Semiconductor Protection Device in Example 3

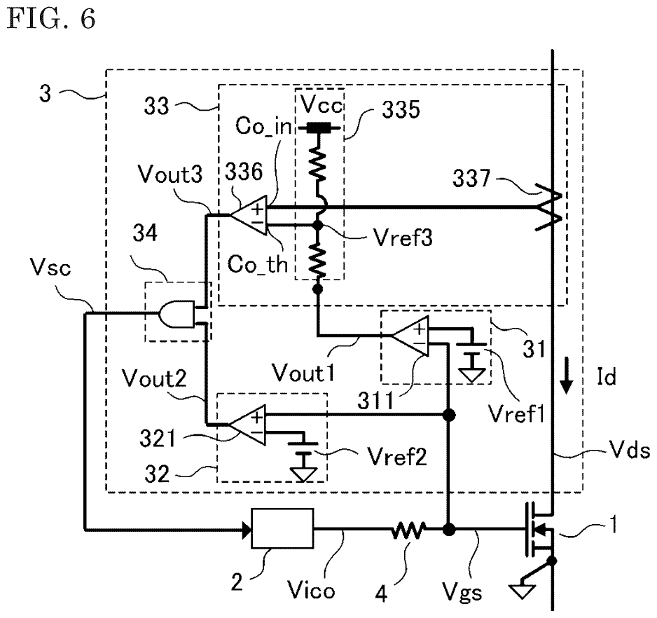

As an example of the semiconductor protection device according to embodiment 1 having the basic configuration shown in FIG. 1, Example 3 will be described with reference to FIG. 6. The same components as in FIG. 2 are denoted by the same reference characters and the description thereof is omitted. In FIG. 6, a difference from Example 1 is that the output determination unit 33 includes a current detector 337.

In FIG. 6, the output determination unit 33 includes the third threshold change section 335, the third comparator 336, and the current detector 337.

The current detector 337 detects the drain current Id of the semiconductor switching element 1, and outputs the detection result to the input terminal Co_in of the third comparator 336.

The third threshold Vref3 is set so that, when the first determination result Vout1 has become high voltage, the third threshold Vref3 becomes not smaller than the drain current Id assumed in normal driving of the semiconductor switching element 1.

In comparison between the third threshold Vref3 and the detection result of the drain current Id outputted from the current detector 337, if the detection result of the drain current Id is greater, the third comparator 336 outputs the third determination result Vout3 as high voltage.

As described above, even in the case of using the current detector 337 in the output determination unit 33, the same effects as in Example 1 of the semiconductor protection device according to embodiment 1 are provided, and in addition, the Desat capacitor 333, the current source 332, and the like are not needed, thus providing an effect of decreasing circuit elements.

### Semiconductor Protection Device in Example 4

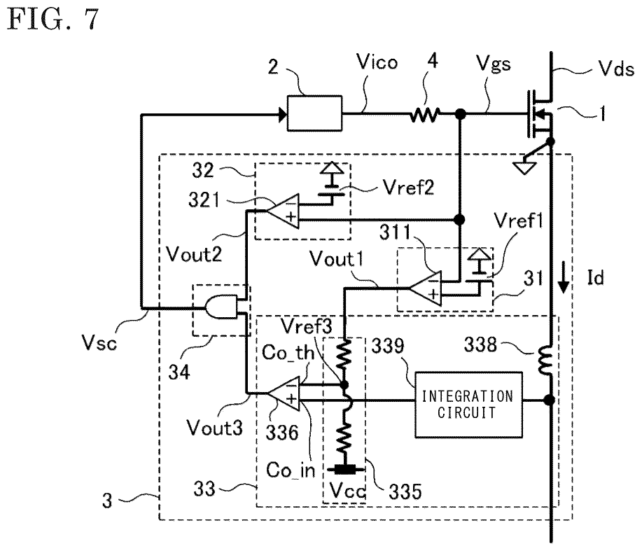

As an example of the semiconductor protection device according to embodiment 1 having the basic configuration shown in FIG. 1, Example 4 will be described with reference to FIG. 7. The same components as in FIG. 6 are denoted by the same reference characters and the description thereof is omitted. In FIG. 7, a difference from Example 3 is that the output determination unit 33 includes an inductor 338 and an integration circuit 339.

In FIG. 7, the output determination unit 33 includes the third threshold change section 335, the third comparator 336, the inductor 338, and the integration circuit 339.

The inductor 338 is connected in series to the semiconductor switching element 1 as shown in FIG. 7, so that the drain current Id flows through the inductor 338.

The inductor 338 may be formed using a parasitic inductance component of a winding or a wire, for example.

The integration circuit 339 detects voltage generated between the inductor 338 and the reference potential of the source terminal of the semiconductor switching element 1, calculates the drain current Id from an integrated value of the detected voltage and the inductance value of the inductor 338, and outputs the drain current Id to the input terminal Co_in of the third comparator 336.

As described above, even in the case of using the inductor 338 and the integration circuit 339 in the output determination unit 33, the same effects as in Example 3 are provided, and in addition, the Desat capacitor 333, the current source 332, and the like are not needed, thus providing an effect of decreasing circuit elements.

### Semiconductor Protection Device in Example 5

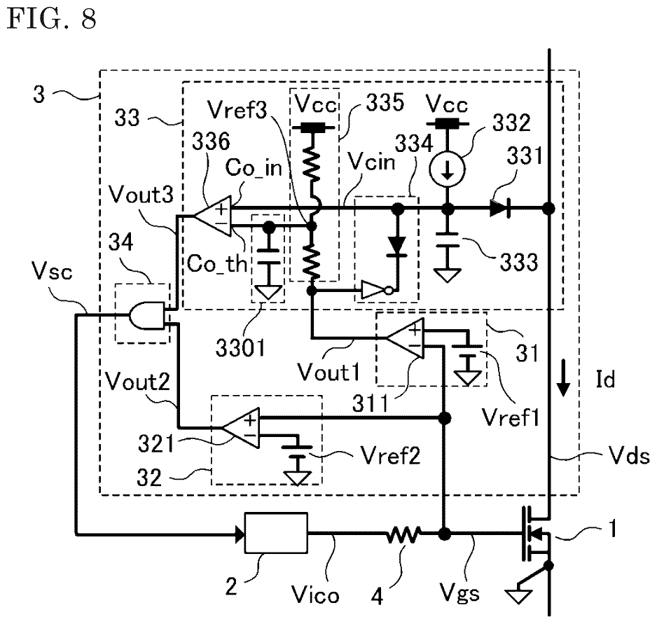

As an example of the semiconductor protection device according to embodiment 1 having the basic configuration shown in FIG. 1, Example 5 will be described with reference to FIG. 8. The same components as in FIG. 2 are denoted by the same reference characters and the description thereof is omitted. In FIG. 8, a difference from Example 1 is that the output determination unit 33 includes a third threshold filter 3301.

For example, the input terminal voltage Vcin of the third comparator 336 in Example 1 increases by a change degree according to the amount of current flowing into the Desat capacitor 333 from the current source 332 and the capacitance of the Desat capacitor 333. Therefore, in a case where the amount of current outputted from the current source 332 varies to increase or in a case where the Desat capacitor 333 is deteriorated to be reduced in capacitance, the increase degree of the input terminal voltage Vcin of the third comparator 336 might increase. In this case, in normal driving of the semiconductor switching element 1, the input terminal voltage Vcin of the third comparator 336 might exceed the threshold input terminal voltage Vco_th of the third comparator 336, and thus the third comparator 336 outputs the third determination result Vout3 as high voltage, leading to erroneous output of the short-circuit detection signal Vsc. Considering such a problem, Example 5 provides a configuration that reduces the speed of change of the threshold input terminal voltage Vco_th of the third comparator 336 from high voltage to the third threshold Vref3.

In FIG. 8, the output determination unit 33 includes the diode 331, the current source 332, the Desat capacitor 333, the detection lock section 334, the third threshold change section 335, the third comparator 336, and the third threshold filter 3301.

The third threshold filter 3301 is configured such that, when the first determination result Vout1 outputted from the first determination unit 31 has become low voltage and thus the third threshold change section 335 outputs the third threshold Vref3, the third threshold filter 3301 reduces the speed of change of the threshold input terminal voltage Vco_th of the third comparator 336 from high voltage to the third threshold Vref3.

### Operation in Normal Driving of Semiconductor Protection Device in Example 5

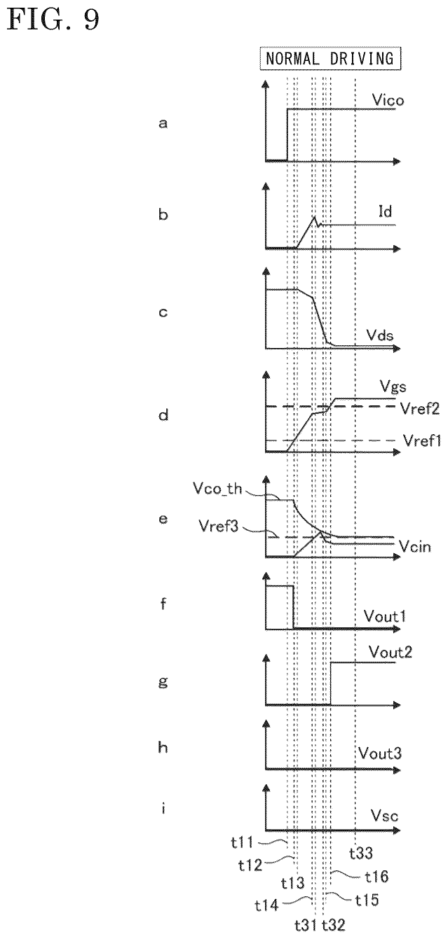

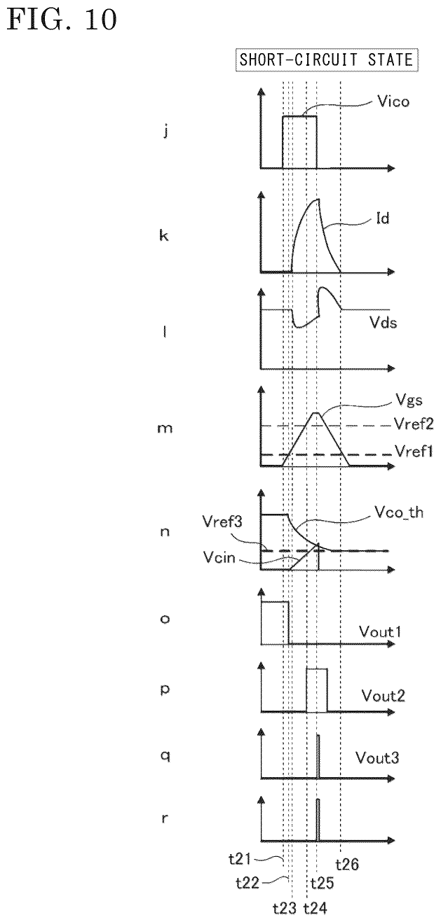

Next, operation of the semiconductor protection device according to Example 5 will be described with reference to FIG. 9 and FIG. 10. FIG. 9 is a time chart illustrating operation in normal driving of the semiconductor switching element 1. The same matters as in FIG. 3 described in Example 1 are denoted by the same reference characters and the description thereof is omitted.

FIG. 9 is different from FIG. 3 in that the increase speed of the input terminal voltage Vcin of the third comparator 336 is fast (see FIG. 9e), and this shows a case where the increase degree of the input terminal voltage Vcin of the third comparator 336 becomes great as described above.

With reference to FIG. 9, during a period from time t31 to time t32, the input terminal voltage Vcin of the third comparator 336 has a value greater than the third threshold Vref3 at time t33 (Vcin in FIG. 9e).

In this case, in the configuration of Example 1, the third determination result Vout3 becomes high voltage during the period from time t31 to time t32. Therefore, in a case where the second determination result Vout2 is set to be high voltage during the period from time t31 to time t32, the short-circuit detection signal Vsc becomes high voltage, so that short-circuit is erroneously detected.

On the other hand, in the configuration of Example 5, as shown in FIG. 9, the speed of change of the threshold input terminal voltage Vco_th of the third comparator 336 to the third threshold Vref3 when the first determination result Vout1 has become low voltage is slow (Vco_th in FIG. 9e), unlike FIG. 3. This is because the change speed of the third threshold Vref3 is reduced by the third threshold filter 3301.

Therefore, the speed of change of the threshold input terminal voltage Vco_th of the third comparator 336 is slow, and the input terminal voltage Vcin of the third comparator 336 does not exceed the third threshold Vref3.

Thus, the third determination result Vout3 becomes low voltage also during the period from time t31 to time t32.

In FIG. 9, during a period from time t11 to time t15, the third determination result Vout3 is retained at low voltage. However, the third threshold Vref3 and the third threshold filter 3301 may be set so that the input terminal voltage Vcin of the third comparator 336 becomes smaller than the threshold input terminal voltage Vco_th of the third comparator 336 before time t15.

### Operation in Short-Circuit Occurring State of Semiconductor Protection Device in Example 5

FIG. 10 is a time chart illustrating operation in driving in a short-circuit occurring state of the semiconductor switching element 1 according to Example 5.

The same matters as in FIG. 4 are denoted by the same reference characters and the description thereof is omitted.

Also in FIG. 10, as in FIG. 9, the increase speed of the input terminal voltage Vcin of the third comparator 336 is fast, unlike FIG. 3.

Also in FIG. 10, as in FIG. 4, the short-circuit detection signal Vsc becomes high voltage and interruption of the drain current Id is completed, whereby the semiconductor switching element 1 can be protected from being broken by short-circuit.

As described above, Example 5 provides the effects of Example 1, and in addition, provides an effect that, even in a case where the increase degree of the input terminal voltage Vcin of the third comparator 336 varies to increase, in normal driving of the semiconductor switching element 1, the semiconductor switching element 1 is prevented from being erroneously determined to be in a short-circuit state and the short-circuit detection signal Vsc is prevented from being outputted.

### Semiconductor Protection Device in Example 6

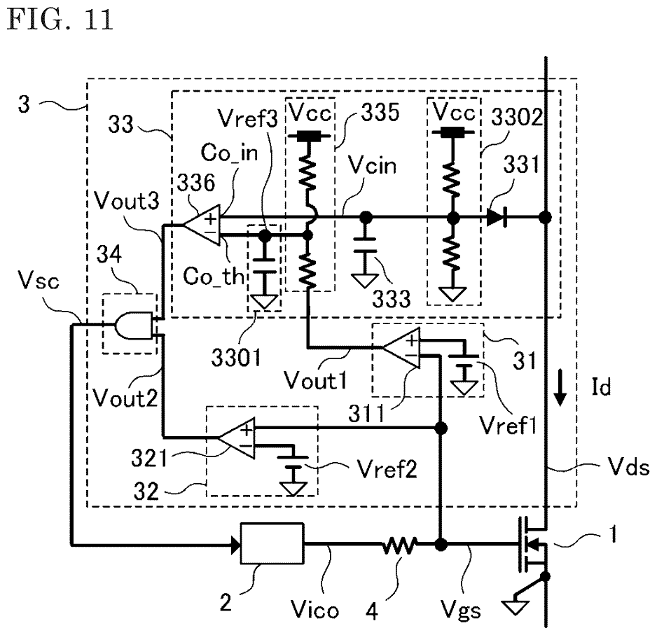

As an example of the semiconductor protection device according to embodiment 1 having the basic configuration shown in FIG. 1, Example 6 will be described with reference to FIG. 11. The same components as in FIG. 8 are denoted by the same reference characters and the description thereof is omitted. In Example 6, a difference from Example 5 is that the output determination unit 33 includes a Vcin initial value setting unit 3302.

For reducing loss in the semiconductor switching element 1, a semiconductor switching element that can be switched between ON and OFF at a higher speed than in conventional art may be used.

For example, in a case of using a semiconductor switching element capable of high-speed switching, such as SiC-MOSFET (Silicon Carbide Metal Oxide Semiconductor Field Effect Transistor) or GaN-HEMT (Gallium Nitride High Electron Mobility Transistor), in the configuration of Example 1 shown in FIG. 2, voltage of the Desat capacitor 333 is discharged through a parasitic capacitance component of the diode 331 connected to the high-potential terminal of the semiconductor switching element 1, at the time of turn-on switching. Thus, short-circuit detection is delayed, leading to breakage of the semiconductor switching element 1.

Considering such a problem, the semiconductor protection device according to Example 6 is configured to perform charging for the input terminal voltage Vcin of the third comparator 336 in advance.

That is, in FIG. 11, the output determination unit 33 includes the diode 331, the Desat capacitor 333, the third threshold change section 335, the third comparator 336, the third threshold filter 3301, and the Vcin initial value setting unit 3302.

The Vcin initial value setting unit 3302 performs charging so that the input terminal voltage Voin of the third comparator 336 becomes a Vcin initial value Vcin_i in advance.

The Vcin initial value Vcin_i is lower than high voltage of the threshold input terminal voltage Vco_th of the third comparator 336, and is higher than the third threshold Vref3.

Specifically, in FIG. 11, the Vcin initial value setting unit 3302 includes two resistors which are connected in series. One end of the series connected resistors is connected to the control power supply Vcc, the other end is connected to a reference potential, and a connection point of the series connected resistors is connected to the input terminal Co_in of the third comparator 336.

In FIG. 11, the Vcin initial value setting unit 3302 includes two resistors, but is not limited to this configuration and may include more resistors.

### Operation in Normal Driving of Semiconductor Protection Device in Example 6

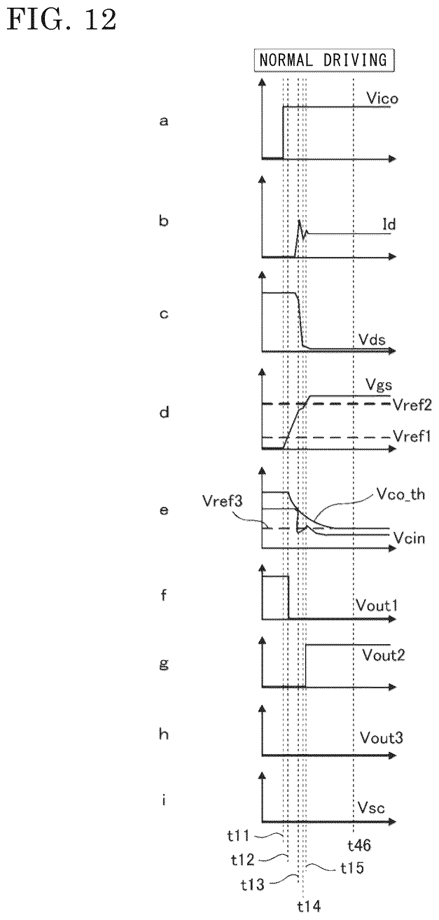

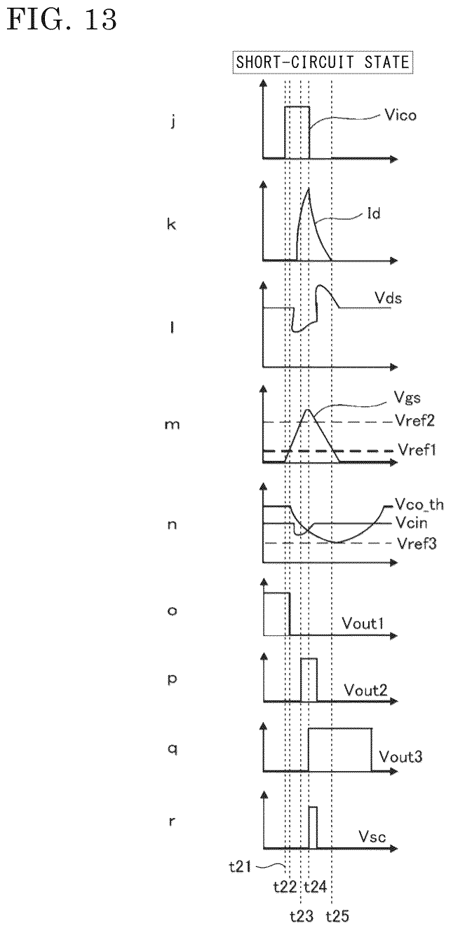

Next, operation of the semiconductor protection device according to Example 6 will be described with reference to FIG. 12 and FIG. 13. FIG. 12 is a time chart illustrating operation in normal driving of the semiconductor switching element 1. In FIG. 12, the increase speed of the drain current Id and the change speed of the gate voltage Vgs are fast, unlike FIG. 9. However, turn-on operation of the semiconductor switching element 1 is the same as in FIG. 9 and therefore the description thereof is omitted.

Unlike FIG. 9, charging is performed so that the input terminal voltage Vcin of the third comparator 336 becomes the Vcin initial value Vcin_i in advance (FIG. 12e).

When the gate voltage Vgs has exceeded the ON voltage threshold of the semiconductor switching element 1, the semiconductor switching element 1 is turned on, the drain current Id starts to be conducted (FIG. 12a), and the drain voltage Vds starts to be reduced (FIG. 12c).

At time t13, the drain voltage Vds greatly changes due to the characteristic of the semiconductor switching element 1. At time t13, voltage of the Desat capacitor 333 is discharged through the parasitic capacitance component of the diode 331 connected to the high-potential terminal of the semiconductor switching element 1, so that the input terminal voltage Vcin of the third comparator 336 sharply drops (FIG. 12e).

At time t14, a Miller period has elapsed, and thus, after time t14, the change speed of the drain voltage Vds is reduced, so that voltage of the Desat capacitor 333 is no longer discharged through the parasitic capacitance component of the diode 331. Therefore, the input terminal voltage Vcin of the third comparator 336 starts to increase to be the Vcin initial value Vcin_i (FIG. 12e).

Thereafter, as the drain voltage Vds is reduced, an electric charge stored in the Desat capacitor 333 is discharged to the semiconductor switching element 1 through the diode 331, so that the input terminal voltage Vcin of the third comparator 336 is reduced (FIG. 12e).

Since the input terminal voltage Vcin of the third comparator 336 is reduced, the input terminal voltage Vcin does not exceed the threshold input terminal voltage Vco_th of the third comparator 336 (FIG. 12e). Therefore, the third determination result Vout3 is retained at low voltage and high voltage is not outputted (FIG. 12h).

During a period from time t11 to time t15, the third determination result Vout3 is retained at low voltage (FIG. 12h). However, the third threshold Vref3 and the third threshold filter 3301 may be set so that the input terminal voltage Vcin of the third comparator 336 becomes smaller than the threshold input terminal voltage Vco_th of the third comparator 336 before time t15.

During the period from time t11 to time t15, the third determination result Vout3 is retained at low voltage. However, the Vein initial value Vcin_i may be set so that the input terminal voltage Vcin of the third comparator 336 becomes smaller than the threshold input terminal voltage Vco_th of the third comparator 336 before time t15.

As described above, setting is made so that the third determination result Vout3 becomes low voltage at least before time t15.

### Operation in Short-Circuit Occurring State of Semiconductor Protection Device in Example 6

FIG. 13 is a time chart illustrating operation in driving in a short-circuit occurring state of the semiconductor switching element 1 according to Example 6.

In FIG. 13, the increase speed of the drain current Id or the change speed of the gate voltage Vgs is fast, unlike FIG. 10. However, turn-on and turn-off operations of the semiconductor switching element 1 are the same as in FIG. 10 and therefore the description thereof is omitted.

In addition, charging is performed so that the input terminal voltage Vcin of the third comparator 336 becomes the Vcin initial value Vcin_i in advance, unlike FIG. 10.

When the gate voltage Vgs has exceeded the ON voltage threshold of the semiconductor switching element 1, the semiconductor switching element 1 is turned on and the drain current Id starts to be conducted (FIG. 13k). When the drain current Id starts to be conducted, the drain voltage Vds starts to be reduced (FIG. 13l), and voltage of the Desat capacitor 333 is discharged through the parasitic capacitance component of the diode 331 connected to the high-potential terminal of the semiconductor switching element, so that the input terminal voltage Vcin of the third comparator 336 sharply drops (FIG. 13n).

As in FIG. 10, since the semiconductor switching element 1 is driven in a short-circuit occurring state, high voltage is applied to the semiconductor switching element 1, so that the input terminal voltage Vcin of the third comparator 336 starts to increase to be the Vcin initial value Vcin_i (FIG. 13n).

At time t24, the input terminal voltage Vcin of the third comparator 336 exceeds the threshold input terminal voltage Vco_th of the third comparator 336 (FIG. 13n), so that the output determination unit 33 outputs the third determination result Vout3 as high voltage (FIG. 13q).

At time t24, a logical conjunction of the second determination result Vout2 and the third determination result Vout3 becomes 1, so that the short-circuit detection unit 34 outputs the short-circuit detection signal Vsc as high voltage (FIG. 13r).

As described above, in Example 6, even in a case where voltage of the Desat capacitor 333 is discharged through the parasitic capacitance component of the diode 331, the short-circuit detection signal Vsc is outputted early, thus providing an effect of protecting the semiconductor switching element 1 from being broken.

### Semiconductor Protection Device in Example 7

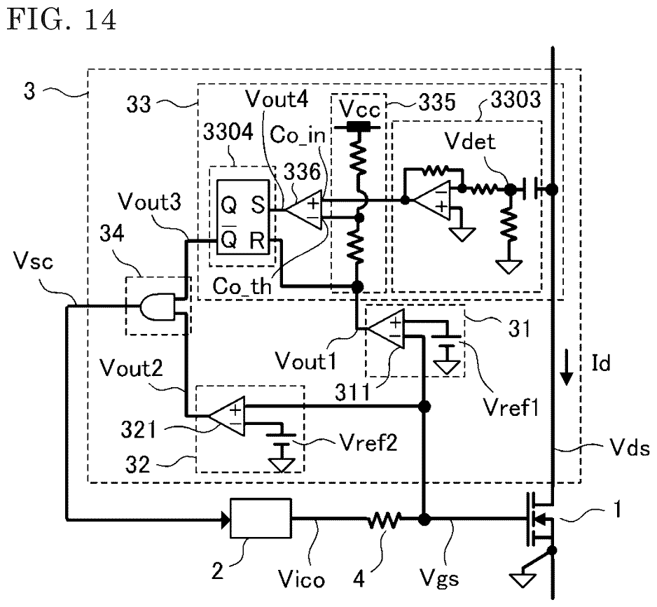

As an example of the semiconductor protection device according to embodiment 1 having the basic configuration shown in FIG. 1, Example 7 will be described with reference to FIG. 14. In FIG. 14, a difference from FIG. 2 in Example 1 is that the output determination unit 33 includes a temporal change detection circuit 3303 and a logic circuit 3304. The same components as in FIG. 2 are denoted by the same reference characters and the description thereof is omitted.

As shown in FIG. 3 and FIG. 4, the change speed of the drain voltage Vds differs between a case of normal driving and a case of driving in a short-circuit condition, and the change degree of the drain voltage Vds in a short-circuit condition is smaller than in normal driving.

Example 7 is made in consideration of the above circumstance, and using the difference in the change speed of the drain voltage Vds, short-circuit of the semiconductor switching element 1 is detected.

In FIG. 14, the output determination unit 33 in Example 7 includes the third threshold change section 335, the third comparator 336, the temporal change detection circuit 3303, and the logic circuit 3304.

In FIG. 14, in comparison between the input terminal voltage Vcin of the third comparator 336 and the threshold input terminal voltage Vco_th of the third comparator 336, if the threshold input terminal voltage Vco_th is greater, the fourth determination result Vout4 is outputted as low voltage. If the input terminal voltage Vcin is greater, the fourth determination result Vout4 is outputted as high voltage.

The temporal change detection circuit 3303 detects temporal change of the high-potential terminal voltage of the semiconductor switching element 1, and outputs the temporal change to the input terminal Co_in of the third comparator 336.

In FIG. 14, the temporal change detection circuit 3303 includes a capacitor having one end connected to the drain terminal of the semiconductor switching element 1, a resistor connected to another end of the capacitor and a reference potential, and an inverting amplifier which outputs a value obtained by inverting the sign of a detection potential Vdet of a connection point between the capacitor and the resistor, to the third comparator 336. However, the temporal change detection circuit 3303 is not limited to the above configuration.

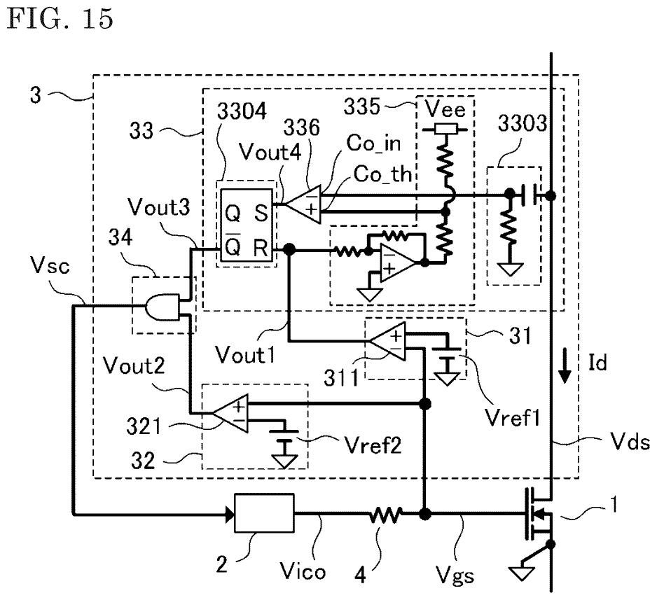

For example, the detection potential Vdet of the connection point between the capacitor and the resistor has a negative-sign voltage value smaller than the reference potential during driving of the semiconductor switching element 1. Therefore, as shown in FIG. 15, a configuration may be made such that, without inversion of the sign of the detection potential Vdet of the connection point between the capacitor and the resistor, the third threshold Vref3 outputted from the third threshold change section 335 is made to be a negative value and comparison in the third comparator 336 is performed with a negative-sign voltage value.

In FIG. 15, the third threshold change section 335 includes two resistors for dividing voltage of a control negative power supply Vee having a negative-sign voltage value, and an inverting amplifier which inverts the sign of the first determination result Vout1. Until the first determination result Vout1 is inputted, the threshold input terminal voltage Vco_th of the third comparator 336 is set to be not greater than the voltage value of the control negative power supply Vee, and when the first determination result Vout1 is inputted, the third threshold Vref3 based on the control negative power supply Vee and the voltage division ratio of the two resistors is outputted to the threshold input terminal Co_th of the third comparator 336.

In comparison between the input terminal voltage Vcin and the threshold input terminal voltage Vco_th of the third comparator 336, if the threshold input terminal voltage Vco_th of the third comparator 336 is smaller, the third comparator 336 outputs the fourth determination result Vout4 as low voltage. If the input terminal voltage Vcin is smaller, the third comparator 336 outputs the fourth determination result Vout4 as high voltage.

The third threshold change section 335 is composed of two resistors for dividing voltage of the control negative power supply Vee having a negative-sign voltage value, and the inverting amplifier which inverts the sign of the first determination result Vout1. However, the third threshold change section 335 is not limited to the above configuration.

In FIG. 14, the logic circuit 3304 is formed by an RS flip-flop circuit, and outputs the third determination result Vout3 as high voltage in a case where the first determination result Vout1 is high voltage and subsequently in a case where the first determination result Vout1 is low voltage and the fourth determination result Vout4 is low voltage.

The logic circuit 3304 outputs the third determination result Vout3 as low voltage in a case where the first determination result Vout1 is low voltage and the fourth determination result Vout4 is low voltage, and continues outputting the third determination result Vout3 as low voltage until the first determination result Vout1 becomes high voltage.

The logic circuit 3304 is formed by an RS flip-flop circuit, but is not limited thereto.

### Operation in Normal Driving of Semiconductor Protection Device in Example 7

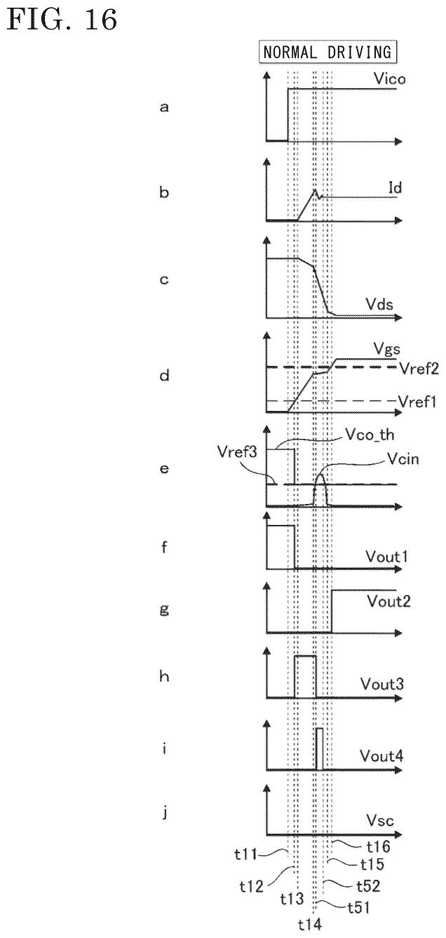

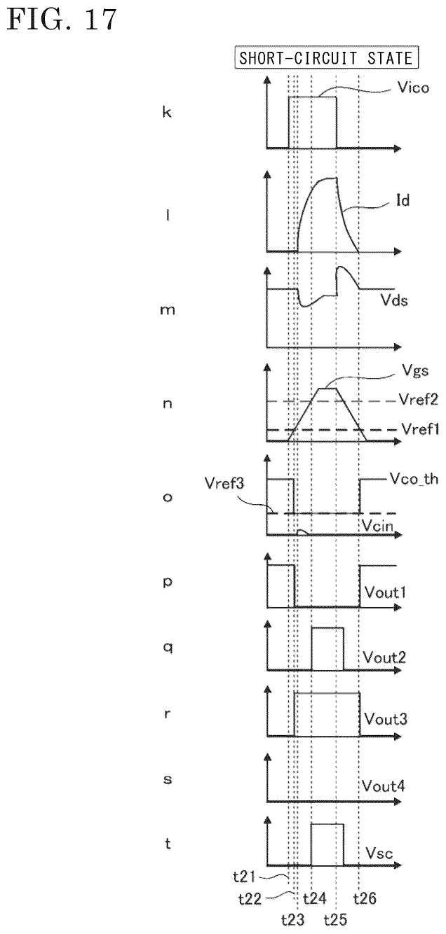

Next, operation of the semiconductor protection device according to Example 7 will be described with reference to FIG. 16 and FIG. 17. FIG. 16 is a time chart illustrating operation in normal driving of the semiconductor switching element 1. The same matters as in FIG. 3 are denoted by the same reference characters and the description thereof is omitted.

In FIG. 16, at time t12, the first threshold Vref1 is exceeded (FIG. 16d), so that the first determination result Vout1 becomes low voltage (FIG. 16f) and the third determination result Vout3 becomes high voltage (FIG. 16h).

At time t13, the drain current Id starts to be conducted to the semiconductor switching element 1 (FIG. 16b) and the drain voltage Vds changes, so that the input terminal voltage Vcin of the third comparator 336 increases. However, since change in the drain voltage Vds is not great, the third threshold Vref3 is not exceeded.

At time t14, the change speed of the drain voltage Vds increases, and the input terminal voltage Vcin of the third comparator 336 greatly increases, so that the third threshold Vref3 is exceeded at time t51 (FIG. 16e). Thus, the fourth determination result Vout4 becomes high voltage (FIG. 16i).

At time t51, fourth determination result Vout4 becomes high voltage and the first determination result Vout1 becomes low voltage (FIG. 16f), so that the third determination result Vout3 becomes low voltage (FIG. 16h).

At time t16, the second determination result Vout2 becomes high voltage (FIG. 16g). However, since the third determination result Vout3 is low voltage (FIG. 16h), the semiconductor switching element 1 is not erroneously determined to be in a short-circuit state.

### Operation in Short-Circuit Occurring State of Semiconductor Protection Device in Example 7

FIG. 17 is a time chart illustrating operation in driving in a short-circuit occurring state of the semiconductor switching element 1 according to Example 7. The same matters as in FIG. 4 are denoted by the same reference characters and the description thereof is omitted.

At time t22, the first threshold Vref1 is exceeded, so that the first determination result Vout1 becomes low voltage and the third determination result Vout3 becomes high voltage.

At time t23, the drain current Id starts to be conducted to the semiconductor switching element 1 (FIG. 17l) and the drain voltage Vds changes (FIG. 17m), so that the input terminal voltage Vcin of the third comparator 336 increases (FIG. 17o). However, since change of the drain voltage Vds is not great (FIG. 17m), the third threshold Vref3 is not exceeded (FIG. 17o).

Before time t24, the input terminal voltage Vcin of the third comparator 336 does not exceed the third threshold Vref3 (FIG. 17o). Therefore, at time t24, the second determination result Vout2 becomes high voltage (FIG. 17q), and the second determination result Vout2 and the third determination result Vout3 both become high voltage. Thus, the short-circuit detection unit 34 outputs the short-circuit detection signal Vsc as high voltage (FIG. 17t).

As described above, in Example 7 of the semiconductor protection device according to embodiment 1, even in a case of detecting short-circuit on the basis of change in the drain voltage, the short-circuit detection signal Vsc is outputted early, thus providing an effect of protecting the semiconductor switching element 1 from being broken.

### Embodiment 2

### Basic Configuration of Semiconductor Protection Device According to Embodiment 2

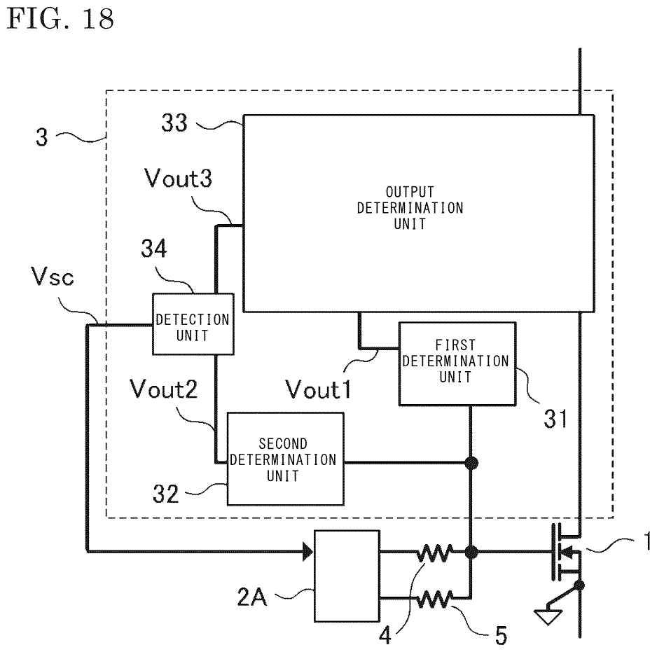

FIG. 18 is a block diagram showing a basic configuration of a semiconductor protection device according to embodiment 2. The semiconductor protection device according to embodiment 2 is different from embodiment 1 in that a soft turn-off gate resistor 5 is provided. When short-circuit is detected, gate turn-off of the semiconductor switching element 1 is performed using the soft turn-off gate resistor 5. The same components as in FIG. 1 are denoted by the same reference characters and the description thereof is omitted.

While short-circuit current is conducted through the semiconductor switching element 1, when short-circuit is detected and the short-circuit current is interrupted, overvoltage occurring in the drain voltage Vds can break the semiconductor switching element 1. Considering such a problem, the soft turn-off gate resistor 5 is provided, and when short-circuit is detected, the semiconductor switching element 1 is turned off using the soft turn-off gate resistor 5.

The soft turn-off gate resistor 5 is connected between a gate drive circuit 2A and the control terminal of the semiconductor switching element 1, and has a greater resistance value than the gate resistor 4. By having a greater resistance value than the gate resistor 4, drain current when the semiconductor switching element 1 is turned off can be made milder than in normal driving.

As described above, the semiconductor protection device according to embodiment 2 can prevent the semiconductor switching element 1 from being broken by overvoltage in turning off of the semiconductor switching element 1 when short-circuit is detected.

### Embodiment 3

### Basic Configuration of Semiconductor Protection Device According to Embodiment 3

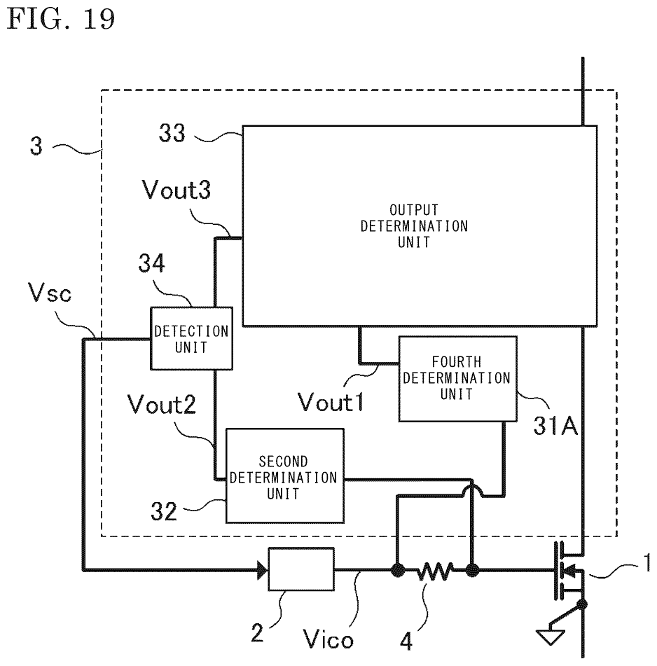

FIG. 19 is a block diagram showing a basic configuration of a semiconductor protection device according to embodiment 3. The semiconductor protection device according to embodiment 3 is different from embodiment 1 in that a fourth determination unit 31A is provided, and is different from embodiment 1 in that the gate drive signal Vico outputted from the gate drive circuit 2 is outputted to the fourth determination unit 31A, and the fourth determination unit 31A outputs the first determination result Vout1 on the basis of the gate drive signal Vico. The same components as in FIG. 1 are denoted by the same reference characters and the description thereof is omitted.

In the semiconductor protection device described in embodiment 1, due to variations in gate capacitances among terminals of semiconductor switching elements, output of the first determination result Vout1 from the first determination unit 31 might be delayed, so that short-circuit detection is delayed, leading to breakage of the semiconductor switching element 1.

Considering such a problem, the fourth determination unit 31A is provided with a fourth threshold Vref4, compares the gate drive signal Vico outputted from the gate drive circuit 2 with the fourth threshold Vref4, and outputs the first determination result Vout1. When the gate drive signal Vico exceeds the fourth threshold Vref4, the fourth determination unit 31A outputs the first determination result Vout1 to the output determination unit 33.

As described above, in the semiconductor protection device according to embodiment 3, the first determination result Vout1 is outputted on the basis of the fourth threshold Vref4, whereby the influence of variations in gate capacitances among the terminals of the semiconductor switching elements 1 can be reduced.

### Embodiment 4

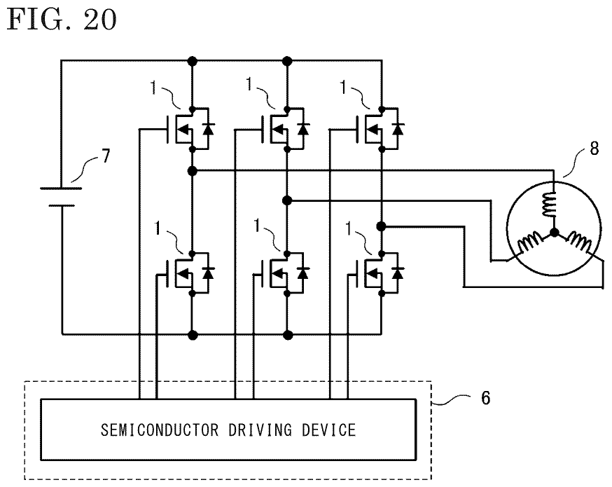

FIG. 20 is a schematic configuration diagram of an electric power conversion device including a semiconductor protection device according to embodiment 4. The electric power conversion device according to embodiment 4 includes a plurality of semiconductor switching elements 1, a semiconductor driving device 6, a high-voltage power supply 7, and a motor 8.

In FIG. 20, the electric power conversion device according to the present embodiment 4 has a bridge circuit composed of six semiconductor switching elements 1, and supplies power supplied from the high-voltage power supply 7, to the motor 8. The semiconductor switching elements 1 are driven by the semiconductor driving device 6. The semiconductor driving device 6 includes the gate drive circuit 2, the semiconductor protection device 3, and the gate resistor 4. The semiconductor driving device 6 may include the soft turn-off gate resistor 5. As the semiconductor protection device 3 included in the semiconductor driving device 6, the semiconductor protection device 3 according to any of embodiments 1 to 3 may be applied.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure.

For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 semiconductor switching element
2, 2A gate drive circuit
3 semiconductor protection device
4 gate resistor
5 soft turn-off gate resistor
6 semiconductor driving device
7 high-voltage power supply
8 motor
31 first determination unit
31A fourth determination unit
32 second determination unit
33 output determination unit
34 short-circuit detection unit
311 first comparator
321 second comparator
331 diode
332 current source
333 Desat capacitor
334 detection lock section
335 third threshold change section
336 third comparator
312 transistor element
337 current detector
338 inductor
339 integration circuit
3301 third threshold filter
3302 Vcin initial value setting unit

1. A semiconductor protection device which outputs a short-circuit detection signal to a gate drive circuit in a case where a semiconductor switching element is determined to be in a short-circuit state, the semiconductor protection device comprising:
a first determination circuitry which outputs a first output signal when gate voltage of the semiconductor switching element has exceeded a predetermined first threshold;
a second determination circuitry which outputs a second output signal when the gate voltage has exceeded a second threshold greater than the first threshold; and
a third determination circuitry which outputs a third output signal when a value based on voltage of the semiconductor switching element or a value based on a value of current flowing through the semiconductor switching element during a period in which the semiconductor switching element is turned ON has exceeded a third threshold, wherein
the third determination circuitry is activated by the third threshold being reduced by the first output signal, and a short-circuit state of the semiconductor switching element is detected on the basis of a logical conjunction of the second output signal and the third output signal.

2. A semiconductor protection device which outputs a short-circuit detection signal to a gate drive circuit in a case where a semiconductor switching element is determined to be in a short-circuit state, the semiconductor protection device comprising:
a first determination circuitry which outputs a first output signal when a gate drive signal for the semiconductor switching element has exceeded a predetermined first threshold;
a second determination circuitry which outputs a second output signal when gate voltage of the semiconductor switching element has exceeded a second threshold; and
a third determination circuitry which outputs a third output signal when a value based on voltage of the semiconductor switching element or a value based on a value of current flowing through the semiconductor switching element during a period in which the semiconductor switching element is turned ON has exceeded a third threshold, wherein
determination operation of the third determination circuitry is activated by the third threshold being reduced by the first output signal, and a short-circuit state of the semiconductor switching element is detected on the basis of a logical conjunction of the second output signal and the third output signal.

3. The semiconductor protection device according to claim 1, wherein
the third determination circuitry is a comparison circuit which compares the third threshold with the value based on the voltage of the semiconductor switching element or the value based on the current flowing through the semiconductor switching element, and the third threshold is retained at high voltage before the first output signal is outputted.

4. The semiconductor protection device according to claim 3, wherein
after the first output signal is outputted to the third determination circuitry, a speed of reduction from the high voltage is set in accordance with the value based on the voltage of the semiconductor switching element or the value based on the current flowing through the semiconductor switching element.

5. The semiconductor protection device according to claim 1, wherein the first threshold is ON voltage of a transistor element.

6. The semiconductor protection device according to claim 1, wherein
the third determination circuitry in a case of comparing the third threshold with the value based on the voltage of the semiconductor switching element has an input connected to a high-potential terminal of the semiconductor switching element via a Desat capacitor and a current source.

7. The semiconductor protection device according to claim 1, wherein
the third determination circuitry in a case of comparing the third threshold with the value based on the current flowing through the semiconductor switching element has an input connected to a current detector provided to a high-potential terminal of the semiconductor switching element.

8. The semiconductor protection device according to claim 1, wherein
the third determination circuitry in a case of comparing the third threshold with the value based on the current flowing through the semiconductor switching element has an input connected via an integration circuit to an inductor provided to a low-potential terminal of the semiconductor switching element.

9. A semiconductor protection device which outputs a short-circuit detection signal to a gate drive circuit in a case where a semiconductor switching element is determined to be in a short-circuit state, the semiconductor protection device comprising:
a first determination circuitry which outputs a first output signal when gate voltage of the semiconductor switching element has exceeded a predetermined first threshold;
a second determination circuitry which outputs a second output signal when the gate voltage has exceeded a second threshold greater than the first threshold; and
a third determination circuitry having a first input connected to a circuit that changes from high voltage to voltage of a third threshold in accordance with the first output signal, and a second input connected to a high-potential terminal of the semiconductor switching element via a Desat capacitor, the second input being set to be higher than the voltage of the third threshold, the third determination circuitry being configured to output a third output signal when a value of the first input has become a value of the second input, wherein
determination operation of the third determination circuitry is activated by the third threshold being reduced by the first output signal, and a short-circuit state of the semiconductor switching element is detected on the basis of a logical conjunction of the second output signal and the third output signal.

10. An electric power conversion device in which a semiconductor switching element is driven by a semiconductor driving device including the semiconductor protection device according to claim 1, to perform power conversion.

11. The semiconductor protection device according to claim 2, wherein
the third determination circuitry is a comparison circuit which compares the third threshold with the value based on the voltage of the semiconductor switching element or the value based on the current flowing through the semiconductor switching element, and the third threshold is retained at high voltage before the first output signal is outputted.

12. The semiconductor protection device according to claim 11, wherein
after the first output signal is outputted to the third determination circuitry, a speed of reduction from the high voltage is set in accordance with the value based on the voltage of the semiconductor switching element or the value based on the current flowing through the semiconductor switching element.

13. The semiconductor protection device according to claim 2, wherein
the first threshold is ON voltage of a transistor element.

14. The semiconductor protection device according to claim 2, wherein
the third determination circuitry in a case of comparing the third threshold with the value based on the voltage of the semiconductor switching element has an input connected to a high-potential terminal of the semiconductor switching element via a Desat capacitor and a current source.

15. The semiconductor protection device according to claim 2, wherein
the third determination circuitry in a case of comparing the third threshold with the value based on the current flowing through the semiconductor switching element has an input connected to a current detector provided to a high-potential terminal of the semiconductor switching element.

16. The semiconductor protection device according to claim 2, wherein
the third determination circuitry in a case of comparing the third threshold with the value based on the current flowing through the semiconductor switching element has an input connected via an integration circuit to an inductor provided to a low-potential terminal of the semiconductor switching element.

17. An electric power conversion device in which a semiconductor switching element is driven by a semiconductor driving device including the semiconductor protection device according to claim 2, to perform power conversion.

18. An electric power conversion device in which a semiconductor switching element is driven by a semiconductor driving device including the semiconductor protection device according to claim 9, to perform power conversion.
